(19) United States
(12) Patent Application Publication
(10) Pub. No.: US 2022/0165103 A1
(43) Pub. Date: May 26, 2022

(54) STACKABLE, CONFIGURABLE MONITORING SYSTEM FOR SHOCK ABSORBERS

(71) Applicant: ITT Manufacturing Enterprises LLC, Wilmington, DE (US)

(72) Inventors: Robert MISEVSKI, Orchard Park, NY (US); John T. KOSCIELNIAK, Blasdell, NY (US)

(73) Assignee: ITT Manufacturing Enterprises LLC, Wilmington, DE (US)

(21) Appl. No.: 17/425,882

(22) PCT Filed: Jan. 29, 2020
(86) PCT No.: PCT/US20/15534

§ 371 Date: Jul. 26, 2021

Related U.S. Application Data
(60) Provisional application No. 62/825,532, filed on Mar. 28, 2019.
(60) Provisional application No. 62/798,161, filed on Jan. 29, 2019.

(51) Int. Cl. G07C 5/08; G07C 5/00; F16F 13/10

(52) U.S. Cl. CPC G07C 5/0808; G07C 5/008; H04L 67/12; F16F 13/105; G07C 5/0825

(57) ABSTRACT

Technologies are generally described for stackable, configurable monitoring systems for shock absorbers or dampers. An example monitoring system may include one or more sensor boards, a processor board, a power supply board, and a communications board stacked together and fitted into a body of a shock absorber (or damper). Each sensor board may condition sensor outputs from one or more sensors. The processor board may process the conditioned sensor outputs and provide data to external computing devices. In some examples, the power supply board may recharge an on-board battery. The stacking order of the boards may be configurable. In other examples, a displacement sensor board may be disposed on the body and measure displacement using a laser module.

### CROSS-REFERENCE TO RELATED APPLICATIONS

This application claims priority to U.S. Provisional Patent Applications Ser. No. 62/798,161 filed on Jan. 29, 2019, entitled “LEAD-LAG DAMPER, FLUID-ELASTIC VIBRATION MOUNT, AND MONITORING SYSTEM” and Ser. No. 62/825,532 filed on Mar. 28, 2019, entitled “LEAD-LAG DAMPER”.

### BACKGROUND

Unless otherwise indicated herein, the materials described in this section are not prior art to the claims in this application and are not admitted as prior art by inclusion in this section.

Shock absorbers or dampers are mechanical or hydraulic devices that absorb and damp shock impulses. They convert kinetic energy from the shock into another form of energy (e.g., heat) to be dissipated. Shock absorbers or dampers may be of different types such as gas-charged, mono- or twin-tube, positive sensitive damping, acceleration sensitive damping, coilover, and so on. Shock absorbers or dampers are used in automotive, aerospace, and similar industries. Depending on application, these devices may be subjected to varying and repeated forces. Thus, shock absorbers or dampers may be subject to failure at unexpected times.

### SUMMARY

The present disclosure generally describes a stackable, configurable monitoring system for shock absorbers or dampers.

According to some examples, a shock absorber monitoring system is described. An example shock absorber monitoring system may include a plurality of stacked circuit boards that include one or more sensor boards, each sensor board configured to condition a sensor output from a sensor; a processor board coupled to the one or more sensor boards and configured to process signals associated with sensor outputs from the one or more sensor boards; a communications board coupled to the processor board, the communications board comprising one or more communication modules configured to facilitate exchange of data and instructions with the processor board; and a power supply board electrically coupled to: the one or more sensor boards, the processor board, and the communications board, where the power supply board is configured to provide power to the plurality of stacked circuit boards. A stacking order of the plurality of stacked circuit boards may be configurable, and the plurality of stacked circuit boards may be arranged to fit inside a portion of the shock absorber.

According to other examples, at least one of the one or more sensor boards may be configured to condition sensor outputs from an on-board sensor and at least one other of the one or more sensor boards may be configured to condition the sensor output from an off-board sensor. Each of the one or more sensor boards may be configured to condition sensor outputs from one or more of a temperature sensor, a force sensor, a pressure sensor, a displacement sensor, an acceleration sensor, or a velocity sensor. The one or more sensor boards may include a sleep mode and an active mode, where the one or more sensor boards are configured to save power in the sleep mode and where the one or more sensor boards are configured to scan sensors in the sleep mode. The plurality of stacked circuit boards may further include a sensor hub board configured to receive sensor outputs from at least a subset of the one or more sensor boards, condition the received sensor outputs, and couple conditioned sensor outputs to the processor board.

According to further examples, the processor board may include one or more processors configured to process signals associated with sensor outputs from the one or more sensor boards based on instructions stored at the processor board and/or instructions received from an external computing device. The processor board may be coupled to one or more visual indicators on a body of the shock absorber. The communications board may include one or more couplers adapted for wired communications with one or more external computing devices. The communications board may also include one or more wired communication modules to facilitate wired communications via one of: a Local Interconnect Network (LIN), a Controller Area Network (CAN), Local Area Networks (LANs), an Ethernet network, various Universal Serial Bus (USB) interfaces, or an optical communication network. The communications board may include a wireless communication module to facilitate wireless communications with one or more external computing devices. The communications board may further include one or more wireless communication modules to facilitate one or more of: near field communications, far field communications, PAN communications, WLAN communications, Bluetooth® communications, Wifi® communications, Zigbee® communications, Z-wave® communications, or satellite communications.

According to yet other examples, each of the plurality of stacked circuit boards may have a cross-sectional shape comprising one of: disk-shaped, doughnut-shaped, or arc-shaped. The monitoring system may further include a displacement sensor board including a laser displacement module, the displacement sensor board located outside a body of the shock absorber, where the displacement module is configured to measure a displacement of a shock cap of the shock absorber relative to the body of the shock absorber. The power supply board may include a battery, a power supply circuit, and a charger module that is adapted to charge the battery. The charger module may include a piezoelectric power generator or a thermoelectric power generator to generate charging power from the shock absorber. The charger module may include a coupler for an external solar power generator to generate charging power.

According to other examples, a shock absorber monitoring system is described. The shock absorber monitoring system may include a displacement sensor board located outside a body of a shock absorber, where the displacement sensor board is configured to measure a displacement of a shock cap of the shock absorber relative to the body of the shock absorber, and a plurality of stacked circuit boards arranged to fit inside a portion of the body of the shock absorber. The plurality of stacked circuit boards may include one or more sensor boards, each sensor board configured to condition a sensor output from a sensor; a processor board coupled to the one or more sensor boards and the displacement sensor board, the processor board configured to process signals associated with sensor outputs from the one or more sensor boards and the displacement sensor board; a communications board coupled to the processor board, the communications board comprising one or more communication modules configured to facilitate exchange of data and instructions with the processor board; and a power supply board electrically coupled to: the one or more sensor boards, the processor board, and the communications board, where the power supply board is configured to provide power to the plurality of stacked circuit boards. A stacking order of the plurality of stacked circuit boards may be configurable.

According to some examples, the one or more sensor boards may be configured to condition sensor outputs from one or more of a temperature sensor, a force sensor, a humidity sensor, a pressure sensor, a displacement sensor, an acceleration sensor, or a velocity sensor. The processor board may be coupled to one or more visual indicators on the body of the shock absorber. The communications board may include one or more couplers for wired communications with one or more external computing devices and/or one or more wireless communication modules to facilitate wireless communications with the one or more external computing devices. Each of the plurality of stacked circuit boards and the displacement sensor board may have a cross-sectional shape comprising one of: disk-shaped, doughnut-shaped, or arc-shaped.

According to further examples, a shock absorber monitoring system is described. The shock absorber monitoring system may include a plurality of stacked circuit boards that include one or more sensor boards, each sensor board configured to condition a sensor output from a sensor; a processor board coupled to the one or more sensor boards and configured to process signals associated with sensor outputs from the one or more sensor boards; a communications board coupled to the processor board, the communications board comprising one or more communication modules configured to facilitate exchange of data and instructions with the processor board; and a power supply board electrically coupled to: the one or more sensor boards, the processor board, and the communications board, where the power supply board is configured to provide power to components of the monitoring system and includes a battery, power supply circuitry, and a charger module to charge the battery. A stacking order of the plurality of stacked circuit boards may be configurable, and the plurality of stacked circuit boards may be arranged to fit inside a portion of a shock absorber.

According to other examples, the charger module may include a piezoelectric power generator or a thermoelectric power generator to generate charging power from the shock absorber. The charger module may include a coupler for an external solar power generator to supply charging power. Each of the one or more sensor boards may be configured to condition sensor outputs from one or more of a temperature sensor, a force sensor, a pressure sensor, a displacement sensor, an acceleration sensor, or a velocity sensor. The processor board may include one or more processors configured to process signals associated with sensor outputs from the one or more sensor boards based on instructions stored at the processor board and/or instructions received from an external computing device. The communications board may include one or more couplers for wired communications with one or more external computing devices and/or one or more wireless communication modules to facilitate wireless communications with the one or more external computing devices. Each of the plurality of stacked circuit boards may have a cross-sectional shape comprising one of: disk-shaped, doughnut-shaped, or arc-shaped.

According to yet other examples, a method for manufacturing a shock absorber monitoring system is described. The method may include forming a plurality of stacked circuit boards by assembling one or more sensor boards, each sensor board including circuitry configured to condition a sensor output from a sensor; assembling a processor board including one or more processors configured to process signals associated with sensor outputs from the one or more sensor boards; assembling a communications board including one or more communication modules configured to facilitate exchange of data and instructions with the processor board; assembling a power supply board configured to provide power to components of the monitoring system; and coupling the one or more sensor boards, the processor board, the communications board, and the power supply board together through stacking, where a stacking order of the plurality of stacked circuit boards is configurable. The method may also include fitting the coupled plurality of stacked circuit boards inside a portion of a shock absorber.

According to some examples, assembling the one or more sensor boards may include configuring at least one of the one or more sensor boards to condition sensor outputs from two or more distinct sensors and configuring at least one other of the one or more sensor boards to condition the sensor output from a single sensor. Assembling the one or more sensor boards may include configuring each of the one or more sensor boards to condition sensor outputs from one or more of a temperature sensor, a force sensor, a pressure sensor, a displacement sensor, an acceleration sensor, or a velocity sensor. Forming the plurality of stacked circuit boards further may include assembling a sensor hub board to receive sensor outputs from at least a subset of the one or more sensor boards, further condition the received sensor outputs, and provide to the processor board; and coupling the sensor hub board to the plurality of stacked circuit boards. Assembling the processor board may further include coupling the processor board to one or more visual indicators on a body of the shock absorber.

According to further examples, assembling the communications board may further include disposing, on the communications board, one or more couplers for wired communications and/or one or more wireless communication modules for wireless communications with one or more external computing devices. The method may further include forming each of the plurality of stacked circuit boards disk-shaped, doughnut-shaped, or arc-shaped. The method may also include assembling a displacement sensor board including a laser displacement module and disposing the displacement sensor board outside a body of the shock absorber such that the displacement module measures a displacement of a shock cap of the shock absorber relative to the body of the shock absorber. Assembling the power supply board may include disposing a battery, power supply circuitry, and a charger module to charge the battery on the power supply board. Disposing the charger module on the power supply board may include disposing a piezoelectric power generator or a thermoelectric power generator on the power supply board to generate charging power from the shock absorber. Disposing the charger module on the power supply board may include disposing a connection for an external solar power generator on the power supply board to generate charging power.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

The foregoing and other features of this disclosure will become more fully apparent from the following description and appended claims, taken in conjunction with the accompanying drawings. Understanding that these drawings depict only several embodiments in accordance with the disclosure and are, therefore, not to be considered limiting of its scope, the disclosure will be described with additional specificity and detail through use of the accompanying drawings, in which:

FIG. 1 illustrates an example shock absorber and a stacked monitoring system to be fitted into the shock absorber;

FIG. 2 illustrates a side cross-sectional view of an example shock absorber and a stacked monitoring system inside the shock absorber;

FIG. 3 illustrates a side perspective view of an example stacked monitoring system with four boards;

FIG. 4 illustrates a bottom perspective view of the example stacked monitoring system FIG. 3 showing the power supply board;

FIG. 5 illustrates a top perspective view of the example stacked monitoring system FIG. 3 showing the communications board;

FIG. 6 illustrates a side cross-sectional view of an example shock absorber and a displacement sensor board fitted onto the shock absorber;

FIG. 7 illustrates top and perspective views of an example displacement sensor board to be fitted onto a shock absorber; and

FIG. 8 illustrates displacement measurement using a laser beam through an example displacement sensor board fitted onto a shock absorber,

all arranged in accordance with at least some embodiments described herein.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented herein. The aspects of the present disclosure, as generally described herein, and illustrated in the Figures, can be arranged, substituted, combined, separated, and designed in a wide variety of different configurations, all of which are explicitly contemplated herein.

This disclosure is generally drawn, inter alia, to methods, apparatus, systems and/or devices associated with stackable, configurable monitoring systems for shock absorbers or dampers.

Briefly stated, technologies are generally described for stackable, configurable monitoring systems for shock absorbers or dampers. An example monitoring system may include one or more sensor boards, a processor board, a power supply board, and a communications board stacked together and fitted into a body of a shock absorber (or damper). Each sensor board may condition sensor outputs from one or more sensors. The processor board may process the conditioned sensor outputs and provide data to external computing devices. In some examples, the power supply board may charge an on-board battery. The stacking order of the boards may be configurable. In other examples, a displacement sensor board may be disposed on the body and measure displacement using a laser module.

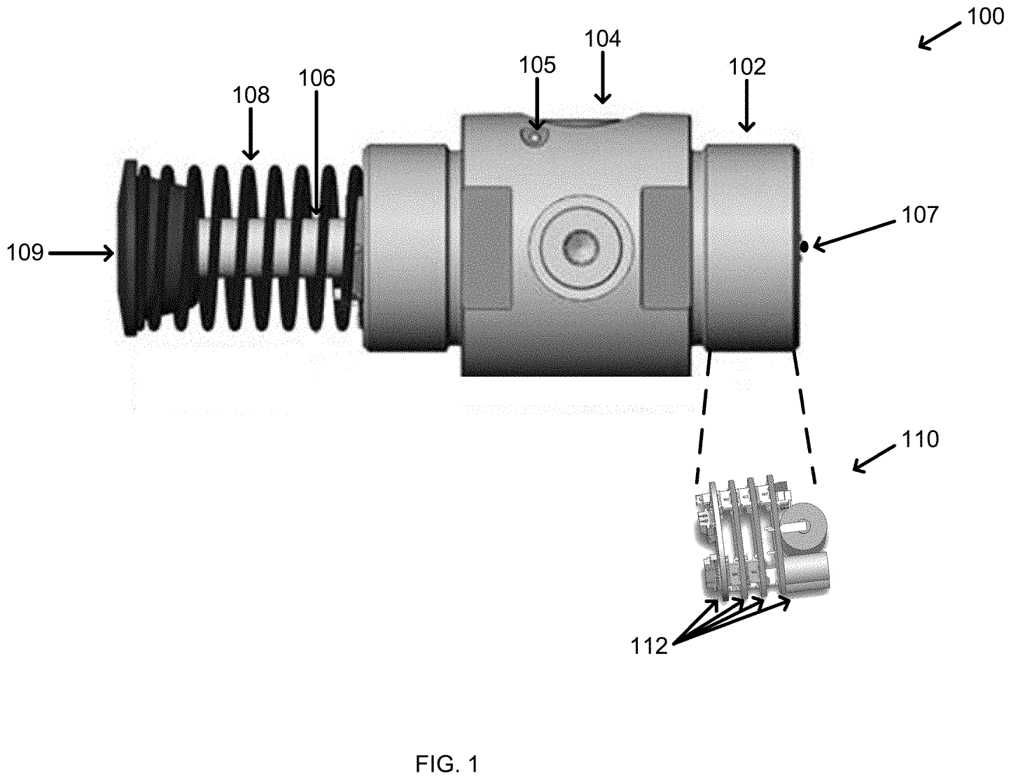

FIG. 1 illustrates an example shock absorber and a stacked monitoring system to be fitted into the shock absorber, arranged in accordance with at least some embodiments described herein.

Shock absorber 100 in FIG. 1 is an example implementation environment for a stacked and configurable monitoring system representative of a variety of shock absorber and damper types. Shock absorber 100 may include a body 104 with a portion 102, a coil 108, a piston cylinder 106, and a shock cap 109. The body 104 may be adapted to house, among other things, a portion of the piston cylinder 106, valves, access ports, one or more fluid chamber(s), and comparable components of the shock absorber. One or more sensors such as pressure sensor 107 may be disposed on or inside the body 104. A stacked monitoring system 110 may include multiple boards 112, which may be housed inside the portion 102 of the body 104.

The operational life of a shock absorber or damper may vary depending on type and application and be on the order of 10,000 to 10,000,000 cycles of operation. Friction and other forces may cause components of a shock absorber to wear and fail. A monitoring system may help assess a status of a shock absorber and allow preventative maintenance or replacement before a potentially catastrophic failure. An example shock absorber monitoring system may include multiple circuit boards stacked together. The boards may include one or more sensor boards configured to condition a sensor output from a sensor that may be located on or off (e.g., remote therefrom) the sensor board, a processor board coupled to the one or more sensor boards and configured to process signals associated with sensor outputs from the sensor boards, and a communications board with one or more communication modules configured to facilitate exchange of data and instructions between the processor board and one or more external computing devices. The monitoring system may further include a power supply board coupled to the other boards and configured to provide power to components of the monitoring system. A stacking order of the stacked boards may be configurable, and the stacked boards may be arranged to fit inside the portion 102 of the shock absorber's body.

In some examples, each of the stacked boards are substantially disk shaped, where the individual boards are stacked in a concentric orientation such that the collection of stacked boards fit snugly inside of the shock absorber's body. The concentric orientation (cylindrical alignment) may be approximately centered about a centrally located axis within the shock absorber body. In other examples, some of the boards may be offset or of different sizes. For example, two boards may substantially fill a cavity in the body of the shock absorber to align the stack overall. Other boards in the stack may be smaller boards in diameter, have different shapes, and/or may be offset from the central axis of the stack.

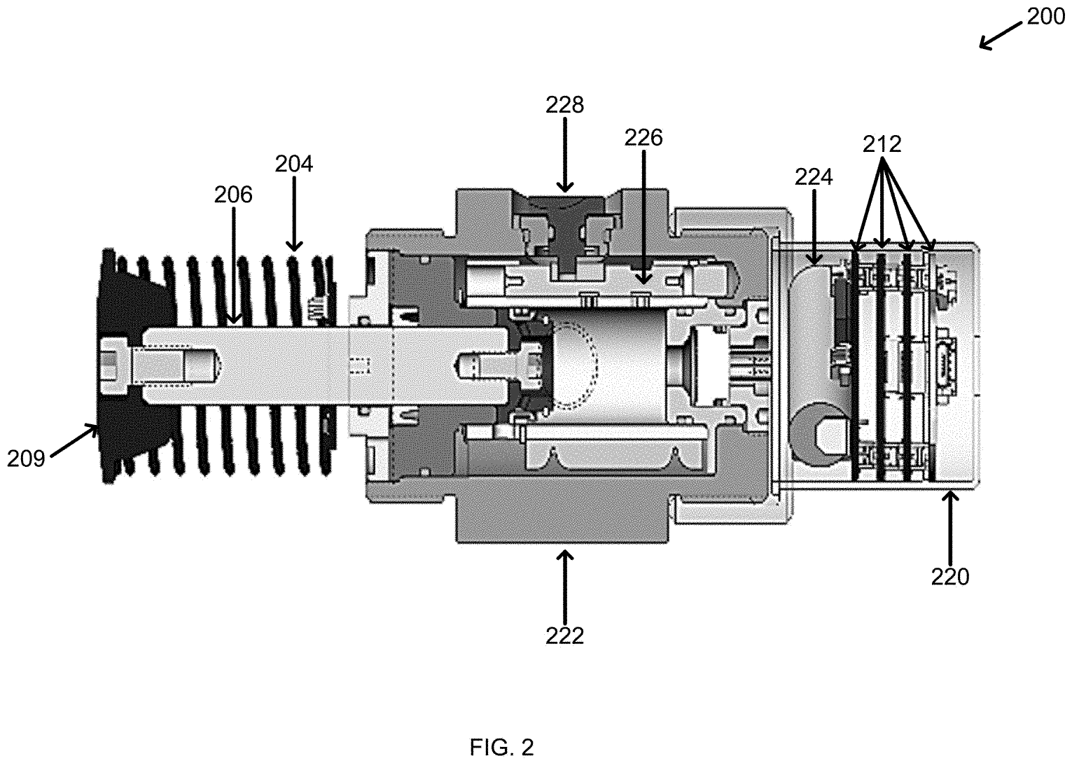

FIG. 2 illustrates a side cross-sectional view of an example shock absorber and a stacked monitoring system inside the shock absorber, arranged in accordance with at least some embodiments described herein.

Shock absorber 200 includes a body 222, a piston cylinder 206, a coil 204, and a shock cap 209. A portion of the piston cylinder 206 and other components such as a secondary chamber 226 or an access port 228 may also be part of the body 222. A monitoring system with stacked boards 212 may be housed inside a portion 220 of the body 222. The stacked boards 212 may include one or more sensor boards, a processor board, a communications board, and a power supply board that is configured to power the stacked boards. The power supply board may include power supply circuitry and a battery 224, for example.

The stacked boards 212 may include one or more sensor boards that are arranged to condition sensor outputs from a single sensor, or the sensor boards may be arranged to condition signals from multiple sensors. In the case of multiple sensors, the sensors may be multiple sensors of either the same type or of different types. Example sensors may include, but are not limited to, a temperature sensor, a humidity sensor, a force sensor, a pressure sensor, a displacement sensor, an acceleration sensor, or a velocity sensor. The sensors may be placed at various locations of the shock absorber 200, for example on the individual sensor boards, at suitable locations inside the body 222, or outside the body 222. Sensor outputs may include various signal types such as voltage, current, digital data signals, analog signals, encoded signals, etc. In some examples, the stacked boards 212 may also include a sensor hub board. The sensor hub board may receive sensor outputs from at least a subset of the sensor boards, (further) condition the received sensor outputs, and couple conditioned sensor outputs to the processor board.

An order and orientation of the stacked boards 212 may be configurable and re-configurable, that is, the boards may be selected and stacked according to the requirements for a particular implementation (number and types of sensors, type and size of shock absorber, etc.). For example, after assembly and manufacturing of the shock absorber 200, individual ones of the boards may be removed, added, or replaced with different boards to customize the stacked monitoring system. The order of the boards may be varied, in some applications, such that the boards may be stacked in a different order. Since the boards in the stacked monitoring system may be varied, the monitoring system is flexible and may be configured and/or reconfigured for specific shock absorbers and varied end-use applications after manufacturing.

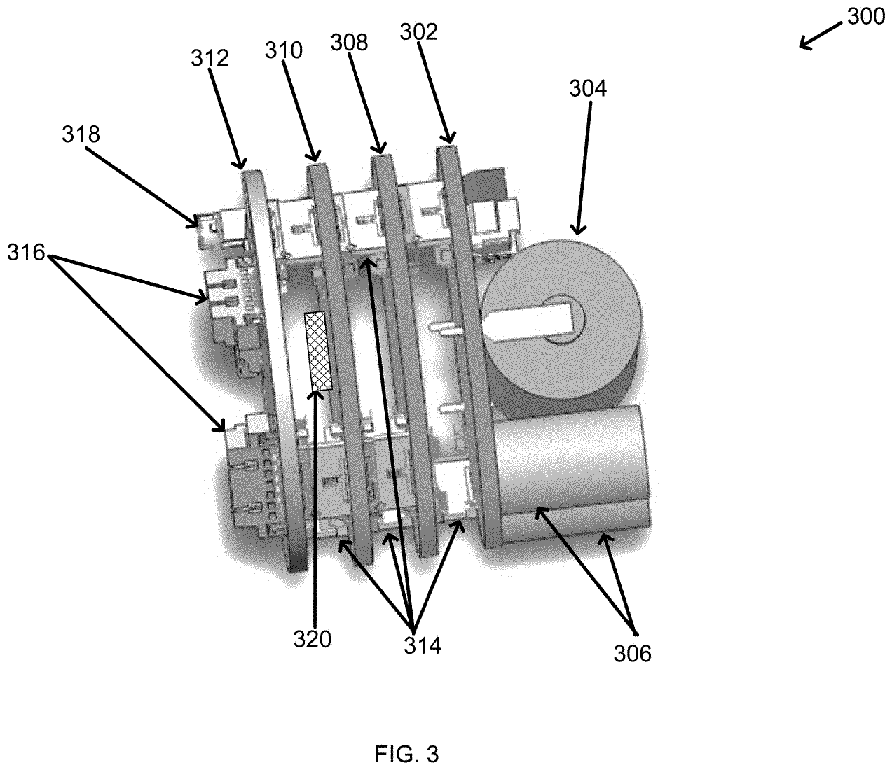

FIG. 3 illustrates a side perspective view of an example stacked monitoring system with four boards, arranged in accordance with at least some embodiments described herein.

Example stacked boards 300 in FIG. 3 include a power supply board 302, a sensor board 308, a processor board 310, and a communications board 312. The power supply board 302 may include a battery 304 and one or more capacitors 306. The processor board 310 may include one or more processors 320. The communications board 312 may include one or more couplers 316 for wired communication with external computing devices and/or a wireless communication module 318 for wireless communications with external computing devices. For examples where the communications board 312 includes a wireless communication module 318, the communications board 312 may have an integrated antenna or a coupler for an external antenna (not shown). The sensor board 308 may include one or more on-board sensor(s) (not shown) or may include a coupler for an off-board (or remote) sensor(s) that is located inside or outside a body of a shock absorber. The boards may be electrically coupled through various couplers 314. The couplers 314 may also function as standoffs that set the spacing between the boards such that spacing and clearances are calibrated by the couplers without the need for any additional components.

Each of the stacked boards 300 may be substantially disk-shaped, doughnut-shaped, or arc-shaped. The collection of the stacked boards 300 are thus shaped to fit into a substantially cylindrically shaped body portion of a shock absorber. In other examples, the cross-sectional shape of the boards may have other shapes such as square, rectangular, polygonal, etc. The boards cross-section dimensions (e.g., radii) may be substantially the same. In still other examples, the sizes of the boards may be different (e.g., some boards may be smaller than others) with the largest board being sized to fit inside the body portion of the shock absorber. Some examples, where the body portion of the shock absorber has a tapered shape, the dimensions of the individual boards may be arranged to match the tapered shape so as to fit snugly therein.

The sensor boards may be configured to scan sensors that are either located on the sensor board or remote therefrom. In some examples, the sensor board may include a sleep mode, where the sensor board may periodically activate to scan one or more of the individual sensors, and thereby preserve power.

Other components on various boards may also be selected for limited power consumption. As discussed in more detail below, the power supply board may be equipped with a charger circuit that may be configured to charge the battery from a variety of different energy sources such as solar, piezoelectric, etc.

In various additional examples, the sensor board or the processor board may be coupled to one or more visual indicators on the body of the shock absorber. For example, an LED may be placed on the body of the shock absorber, where activation of the LED by the sensor board or the processor board may be used to indicate an alarm when an alarm condition is detected through one or more of the sensors (e.g., a temperature exceeds a threshold).

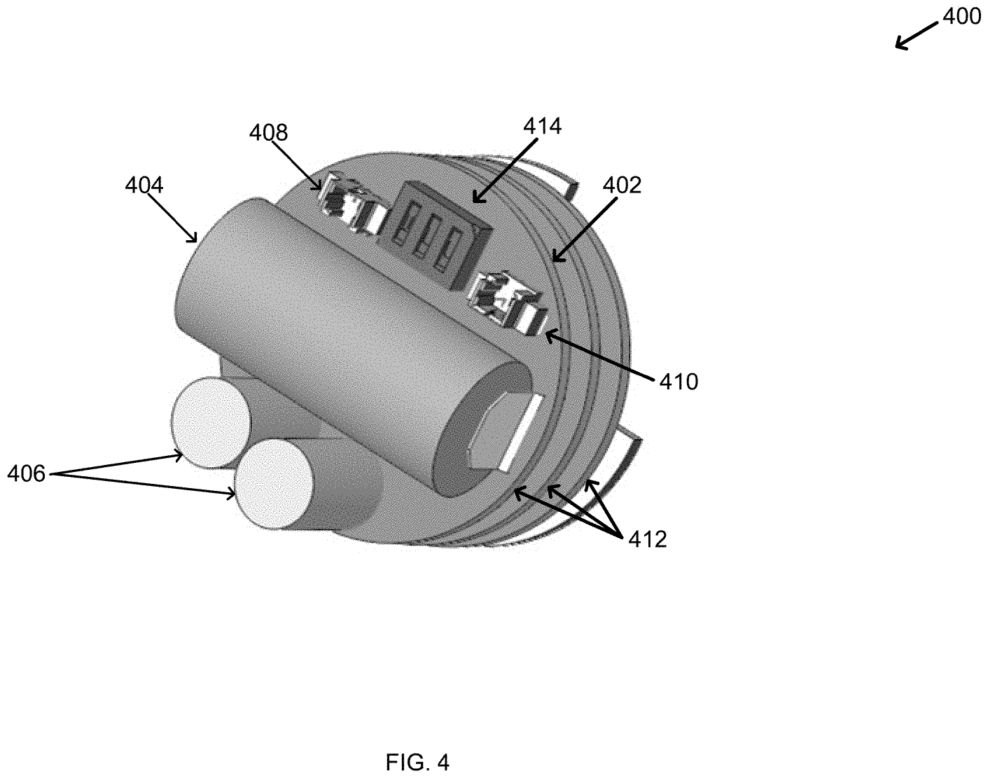

FIG. 4 illustrates a bottom perspective view of the example stacked monitoring system FIG. 3 showing the power supply board, arranged in accordance with at least some embodiments described herein.

The stacked boards 412 in diagram 400 are shown with the power supply board 402 positioned at and end of the stack (e.g., a top or a bottom portion of the stack). In this example, the power supply board 402 includes power supply circuitry such as a battery 404, capacitors 406, couplers 408, 410, and a component 414.

Although illustrated at the end of the stack, this position of the power supply board 402 in the stack is a design choice that was selected to allow the larger components such as the batter 404 and capacitors 406 to have sufficient room and clearance from the other boards in the stack. In other examples, the power supply board may be implemented with different components to allow the power supply board to be in a different position of the stack.

Battery 404 may be a replaceable battery or a rechargeable battery. In the case of a rechargeable battery, a charger circuit (e.g., component 414) may be adapted to facilitate charging (or recharging) of the battery from an external power source through one or more of the couplers 408, 410. The charger circuit may be configured to receive a signal (e.g., current, voltage, power, etc.) from the external power source, process the received signal (e.g., regulate the charge rate, voltage, current, etc.) and provide controlled delivery of charge to the rechargeable battery. Example external power sources may include a solar power source, a piezoelectric power source (e.g., generating electrical energy to charge the battery from mechanical energy captured in the shock absorber), or a thermoelectric power source (e.g., generating electrical energy to charge the battery from heat dissipated in the shock absorber), to name a few.

Component 414 may represent circuitry other than the charge circuit described above. For example, component 414 may include a configurable switch that may be used to select various power settings, power conditioning circuitry or others (e.g., Silicon Labs® EFM32 Arm cortex processor).

A size and type of the battery 404 (and capacitors 406) may be selected based on a configuration of the stacked boards 412. For example, larger batteries may be used for higher number of sensor boards or when sensors with higher power consumption are to be used.

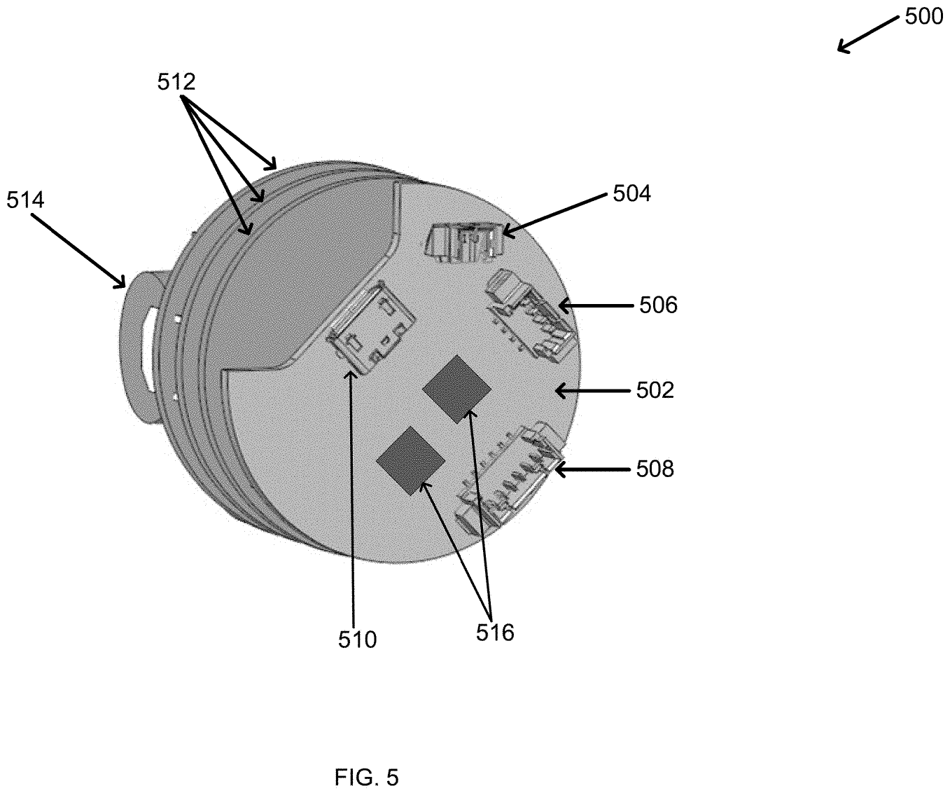

FIG. 5 illustrates a top perspective view of the example stacked monitoring system FIG. 3 showing the communications board, arranged in accordance with at least some embodiments described herein.

In the perspective view of diagram 500, stacked boards 512 are shown with the communications board 502 on an end of the stack (e.g., a top or a bottom portion of the stack). A portion of battery 514 is also visible from the power supply board at the opposite end of the stacked boards 512. The communications board 502 includes couplers 506, 508, 510 for connection to external devices and/or wireless communication module 504. The communications board 502 may also include one or more processors and/or communication modules 516.

The communications board 502 may be configured to communicate with external computing devices employing standardized or proprietary communication protocols. In examples that include a wireless communications, the wireless communications module 504 may be configured for near-field or far-field communications using various communication standards such as radio frequency (RF) identification standards, wireless area network standards (WiFi 802.11, WiMax 802.16 etc., Bluetooth, PAN, WLAN, Bluetooth® or Wifi®, Zigbee®, Z-wave®, etc.), or even satellite communications. The wireless communication module 504 may include an integrated antenna or have a coupler for an external antenna to be coupled to the module.

In examples that include wired communications, one or more of the couplers 506, 508, 510 may be selected to facilitate a particular type of wired connection type. For example, one or more of the couplers may be used to connect to a Local Interconnect Network (LIN), a Controller Area Network (CAN), Local Area Networks (LANs), an Ethernet network, various Universal Serial Bus (USB) interfaces, or an optical communication network. Thus, the couplers may include a USB type coupler (e.g., a USB-A, USB-B, USB-C, mini-USB, micro-USB interfaces, etc.). LIN and CAN are, among other types of networks, examples of modern automotive networks for different applications. The increasing number of sensors in and on a vehicle for a wide range of applications such as those discussed herein may be interfaced to different networks capable of carrying data at rates ranging from 10 to 20 kbit/s (e.g., LIN) to 100 Mbit/s (e.g., Ethernet).

Processors or other communication modules 516 may be integrated circuits (ICs) configured to process signals for various communication protocols. In some examples, sensor parameters may be stored in volatile or non-volatile storage devices such as RANI, ROM, EEPROM, flash memory or other memory technology, solid state drives (SSDs), optical storage devices, magnetic disk storage, or other magnetic storage devices. Raw or conditioned sensor outputs may be similarly stored as well. Sensor outputs may be conditioned, network communications may be managed, and sensors and other devices may be controlled by a single processor or multiple processors. The processors may be implemented as a single integrated circuit (IC) or in a distributed fashion as multiple ICs (e.g., multi-core devices). MC33662 by Freescale Semiconductor®, TH8080 by Melexis®, and SPC560P44 by STMicroelectronics® are some example processors, to name a few. Communication modules may be implemented also as single or multiple ICs with auxiliary components. For example, serial universal asynchronous receiver/transmitter (UART) embedded into microcontrollers such as the PIC18 by Microchip® may be used to provide communications.

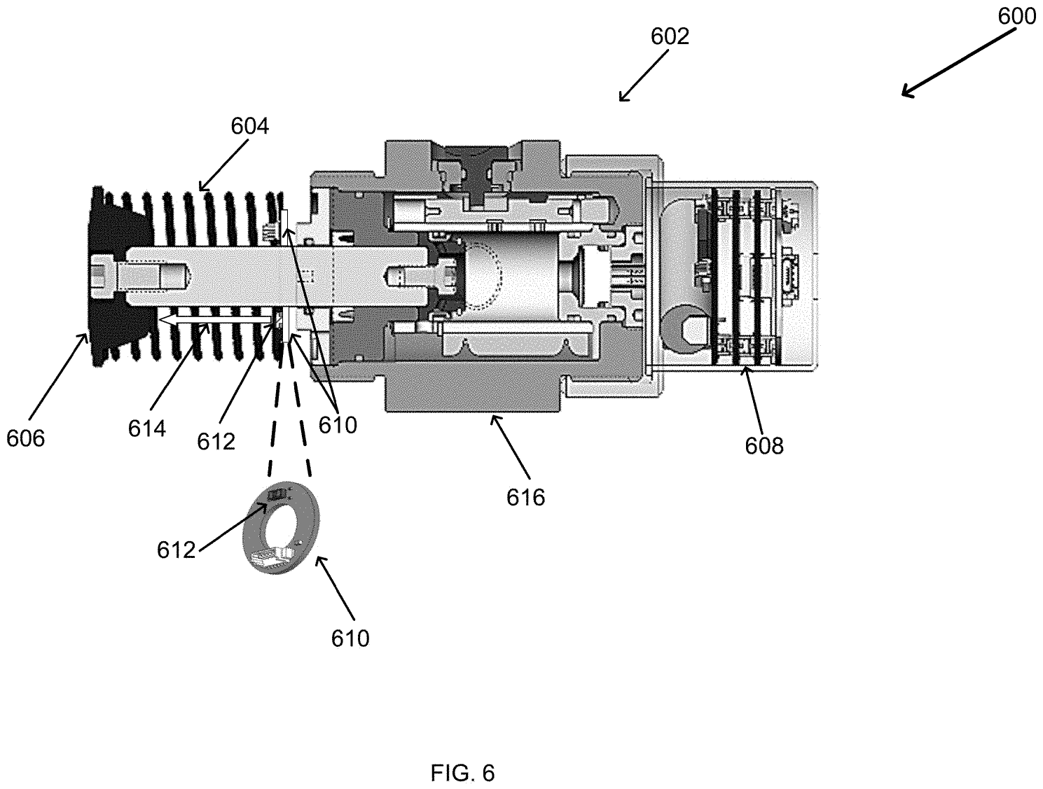

FIG. 6 illustrates a side cross-sectional view of an example shock absorber and a displacement sensor board fitted onto the shock absorber, arranged in accordance with at least some embodiments described herein.

Shock absorber 602 in diagram 600 includes a body 616, a coil 604, and a shock cap 606. A monitoring system with stacked boards 608 may be housed inside a portion of the body 616. In addition to the stacked boards 608, the monitoring system may also include a displacement sensor board 610 located outside of the body 616. The displacement sensor board 610 may include a laser module 612, which is adapted to measure a displacement of the shock absorber 602 by bouncing a laser beam 614 from a surface of the shock cap 606.

As discussed above, the stacked boards 608 may include various sensor boards, a power supply board, a processor board, and a communications board. The additional displacement sensor board 610, which is separate from the stacked boards 610 may be electrically and communicatively coupled to the stacked boards (e.g., through wires or wirelessly) such that it can receive power from the power supply board, provide conditioned sensor outputs to the processor board, and receive instructions from either the communications board or the processor board. In some examples, the displacement sensor board 610 may be placed on the body 616 where the body and the coil meet. The stacked boards 608 may include further displacement sensor boards as well.

In some examples, a shock absorber monitoring system may be manufactured by forming multiple stacked circuit boards and fitting the stacked circuit boards inside a portion of a shock absorber. The stack of boards may be formed by assembling one or more sensor boards with circuitry to condition a sensor output from a sensor on or off the sensor board. A processor board with one or more processors to process signals associated with sensor outputs from the sensor boards may be assembled along with a communications board including one or more communication modules to facilitate exchange of data and instructions between the processor board and one or more external computing devices (not shown). A power supply board to provide power to components of the monitoring system may also be assembled with the one or more sensor boards, the processor board, the communications board, and the power supply board, coupled together through stacking. Couplers of individual boards may act as standoffs and the stacking order may be configurable based on needed sensors.

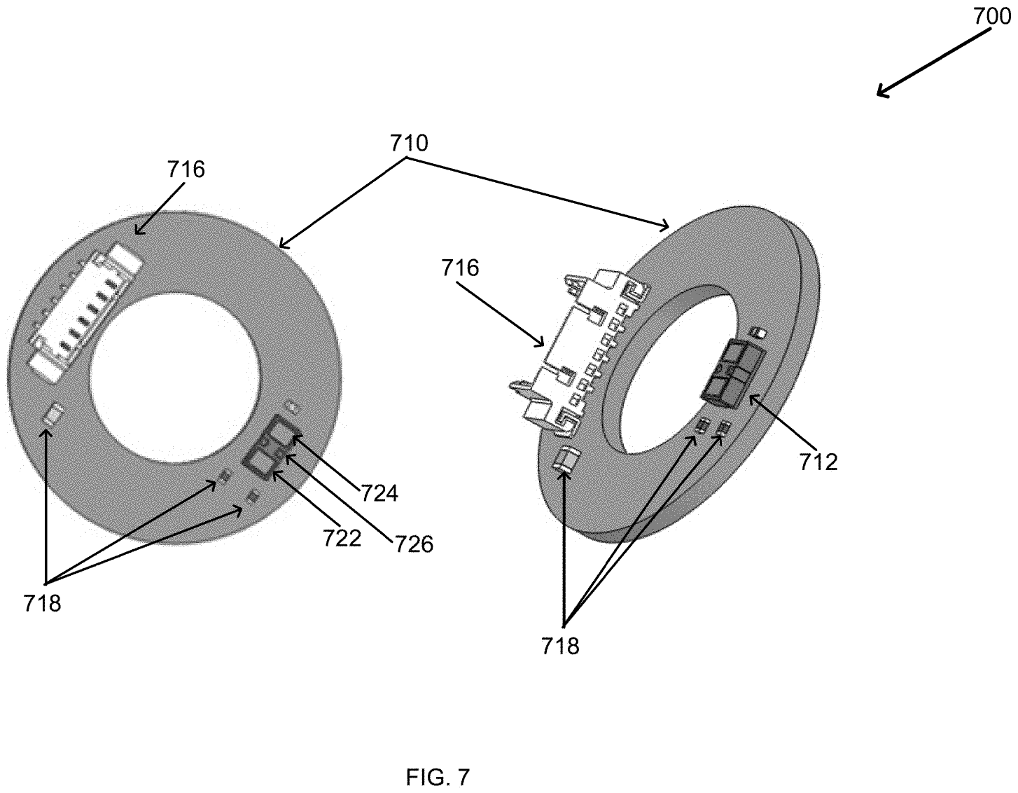

FIG. 7 illustrates top and perspective views of an example displacement sensor board to be fitted onto a shock absorber, arranged in accordance with at least some embodiments described herein.

The top and perspective views of the example displacement sensor board 710 in diagram 700 shows a coupler 716, a laser module 712, and other components 718. The laser module 712 may include a laser emitter 726 and one or more laser detectors 722, 724.

The coupler 716 may provide electrical and communication signals to the other boards on the stacked boards as discussed previously. Other components 718 may be any variety of electrical components such as resistors, capacitors, inductors, diodes, transistors, analog circuits and digital logic circuits (e.g., discrete or integrated circuits) and any other circuitry associated with the operation of the laser module 712 and coupler 716 (e.g., to condition sensor output, to condition supplied power, etc.). In some examples, a power level and a wavelength of a laser beam emitted by the laser module 712 may be selected based on an expected environment of the shock absorber. For example, if a dirty environment (e.g., dust, grease, oil, and smoke present in an external automotive application) is expected, a power level may be increased for the laser beam. If an exceptionally humid environment with water particles is expected, a wavelength of the laser beam may be changed or selected to better fit the humid environment.

The displacement sensor board 710 may be disk-shaped, doughnut-shaped, or arc-shaped similar to the other boards in the stack but may also be differently shaped as may be implemented separate from the stack. In some examples, a generic circuit board with the prerequisite shape and size may be designed to accommodate various component configurations associated with the different boards of the monitoring system. Then, each board may be produced by selecting and disposing appropriate components on the generic board for each type of board. Thus, the different boards of the monitoring system may share a single (or two) circuit boards with different components and couplers.

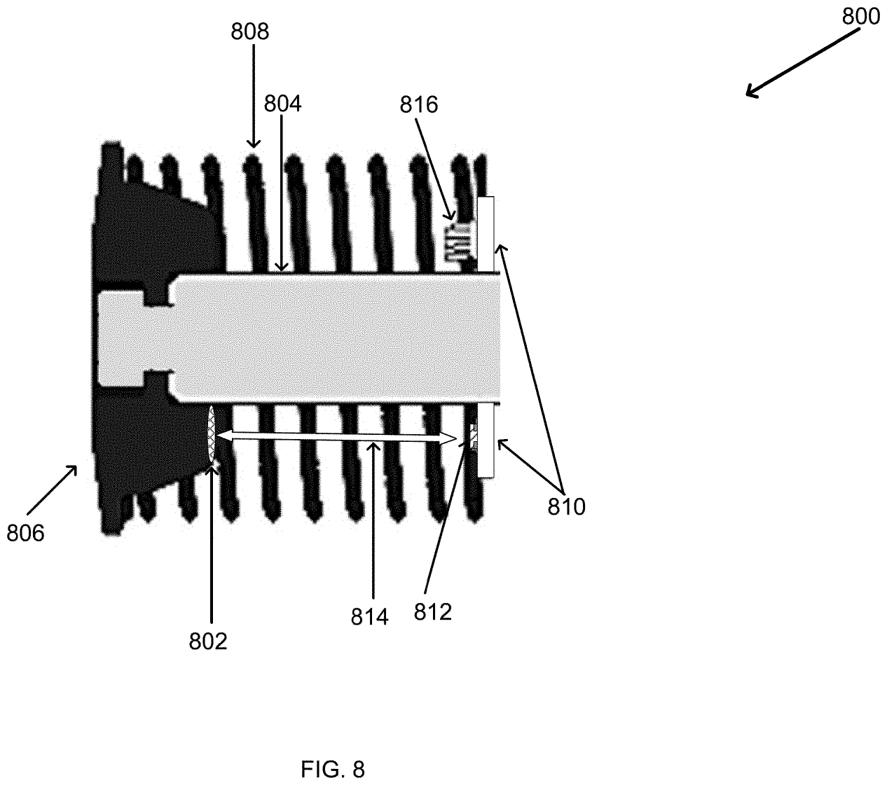

FIG. 8 illustrates displacement measurement using a laser beam through an example displacement sensor board fitted onto a shock absorber, arranged in accordance with at least some embodiments described herein.

Diagram 800 shows a displacement sensor board 810 placed at one end of coil 808 with a coupler 816 and laser module 812. The displacement sensor board 810 may be fitted about a piston cylinder 804. The laser module 812 may be configured to emit a laser beam 814 toward the shock cap 806 and detect a reflection of the laser beam from a surface 802 of the shock cap 806 to measure displacement of the shock absorber.

The displacement sensor board 810 may be mounted at a location relative to a detection light path for the displacement measurement. In some examples, the displacement sensor board 810 may be shaped to allow the piston cylinder 804 to pass therethrough (e.g., doughnut-shaped or arc shaped (e.g., a region of the displacement sensor board wraps around at least a portion of the piston cylinder). Coupler 816 may allow power signals and communication signals to be exchanged with the stack of boards inside the body of the shock absorber. To enhance a reflection of the laser beam 814 from the shock cap 806, the surface 802 of the shock cap 806 may be prepared or treated (e.g., enhanced opaqueness, black paint or epoxy, etc.).

The benefits of the presently disclosed monitoring systems are numerous. For example, the stacked board monitoring systems may allow heretofore unmeasurable parameters of shock absorber or damper parameters to be measured, or other parameters such as temperature, pressure, etc. may be measured more accurately in compact and configurable devices. Combinations of sensors applicable or desired for different types of shock absorbers or dampers, or for different types of applications, may be configured at manufacturing assembly by selecting the boards and their order accordingly. In other examples, order and configuration of the boards may be modified post-manufacturing (e.g., during routine maintenance or repairs). An example monitoring system may be entirely or partially powered by energy harvested from the shock absorber (piezoelectric or thermoelectric) or by solar power, thus allowing a self-sufficient monitoring system to be implemented. Furthermore, a displacement sensor board as discussed herein may allow accurate displacement measurements through the use of a laser.

The present disclosure is not to be limited in terms of the particular embodiments described in this application, which are intended as illustrations of various aspects. Many modifications and variations can be made without departing from its spirit and scope. Functionally equivalent methods and apparatuses within the scope of the disclosure, in addition to those enumerated herein, are possible from the foregoing descriptions. Such modifications and variations are intended to fall within the scope of the appended claims. The present disclosure is to be limited only by the terms of the appended claims, along with the full scope of equivalents to which such claims are entitled. The terminology used herein is for the purpose of describing particular embodiments only and is not intended to be limiting.

The herein described subject matter sometimes illustrates different components contained within, or connected with, different other components. Such depicted architectures are merely examples, and in fact, many other architectures may be implemented which achieve the same functionality. In a conceptual sense, any arrangement of components to achieve the same functionality is effectively “associated” such that the desired functionality is achieved. Hence, any two components herein combined to achieve a particular functionality may be seen as “associated with” each other such that the desired functionality is achieved, irrespective of architectures or intermediate components. Likewise, any two components so associated may also be viewed as being “operably connected”, or “operably coupled”, to each other to achieve the desired functionality, and any two components capable of being so associated may also be viewed as being “operably couplable”, to each other to achieve the desired functionality. Specific examples of operably couplable include but are not limited to physically connectable and/or physically interacting components and/or wirelessly interactable and/or wirelessly interacting components and/or logically interacting and/or logically interactable components.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

In general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation, no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations).

Furthermore, in those instances where a convention analogous to “at least one of A, B, and C, etc.” is used, in general, such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

For any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” and the like include the number recited and refer to ranges which can be subsequently broken down into subranges as discussed above. Finally, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

While various aspects and embodiments have been disclosed herein, other aspects and embodiments are possible. The various aspects and embodiments disclosed herein are for purposes of illustration and are not intended to be limiting, with the true scope and spirit being indicated by the following claims.

What is claimed is:

1. A shock absorber monitoring system comprising:
a plurality of stacked circuit boards comprising:
one or more sensor boards, each sensor board configured to condition a sensor output from a sensor;
a processor board coupled to the one or more sensor boards and configured to process signals associated with sensor outputs from the one or more sensor boards;
a communications board coupled to the processor board, the communications board comprising one or more communication modules configured to facilitate exchange of data and instructions with the processor board; and
a power supply board electrically coupled to: the one or more sensor boards, the processor board, and the communications board, wherein the power supply board is configured to provide power to the plurality of stacked circuit boards;
wherein a stacking order of the plurality of stacked circuit boards is configurable, and the plurality of stacked circuit boards is arranged to fit inside a portion of the shock absorber.

2. The monitoring system of claim 1, wherein
at least one of the one or more sensor boards is configured to condition sensor outputs from an on-board sensor and at least one other of the one or more sensor boards is configured to condition the sensor output from an off-board sensor, and
the sensor includes a temperature sensor, a force sensor, a pressure sensor, a displacement sensor, an acceleration sensor, or a velocity sensor.

3. The monitoring system of claim 1, wherein the one or more sensor boards include a sleep mode and an active mode, wherein the one or more sensor boards are configured to save power in the sleep mode and wherein the one or more sensor boards are configured to scan sensors in the sleep mode.

4. The monitoring system of claim 1, the plurality of stacked circuit boards further comprising a sensor hub board configured to:
receive sensor outputs from at least a subset of the one or more sensor boards,
condition the received sensor outputs, and
couple conditioned sensor outputs to the processor board.

5. The monitoring system of claim 1, wherein the processor board includes one or more processors configured to process signals associated with sensor outputs from the one or more sensor boards based on instructions stored at the processor board and/or instructions received from an external computing device.

6. The monitoring system of claim 1, wherein the processor board is coupled to one or more visual indicators on a body of the shock absorber.

7. The monitoring system of claim 1, the communications board comprising one or more of:
a coupler adapted for wired communications with one or more external computing devices;
a wired communication module to facilitate wired communications via one of: a Local Interconnect Network (LIN), a Controller Area Network (CAN), Local Area Networks (LANs), an Ethernet network, various Universal Serial Bus (USB) interfaces, or an optical communication network;
a wireless communication module to facilitate one or more of: near field communications, far field communications, PAN communications, WLAN communications, Bluetooth® communications, Wifi® communications, Zigbee® communications, Z-wave® communications, or satellite communications.

8. The monitoring system of claim 1, wherein each of the plurality of stacked circuit boards has a cross-sectional shape comprising one of: disk-shaped, doughnut-shaped, or arc-shaped.

9. The monitoring system of claim 1, further comprising:
a displacement sensor board including a laser displacement module, the displacement sensor board located outside a body of the shock absorber, wherein the displacement module is configured to measure a displacement of a shock cap of the shock absorber relative to the body of the shock absorber.

10. The monitoring system of claim 1, wherein
the power supply board includes a battery, a power supply circuit, and a charger module that is adapted to charge the battery, and
the charger module comprises a piezoelectric power generator or a thermoelectric power generator to generate charging power from the shock absorber and/or a coupler for an external solar power generator to generate charging power.

11. A shock absorber monitoring system comprising:
a displacement sensor board located outside a body of a shock absorber, wherein the displacement sensor board is configured to measure a displacement of a shock cap of the shock absorber relative to the body of the shock absorber;
a plurality of stacked circuit boards arranged to fit inside a portion of the body of the shock absorber, the plurality of stacked circuit boards comprising:
one or more sensor boards, each sensor board configured to condition a sensor output from a sensor;
a processor board coupled to the one or more sensor boards and the displacement sensor board, the processor board configured to process signals associated with sensor outputs from the one or more sensor boards and the displacement sensor board;
a communications board coupled to the processor board, the communications board comprising one or more communication modules configured to facilitate exchange of data and instructions with the processor board; and
a power supply board electrically coupled to: the one or more sensor boards, the processor board, and the communications board, wherein the power supply board is configured to provide power to the plurality of stacked circuit boards;
wherein a stacking order of the plurality of stacked circuit boards is configurable.

12. The monitoring system of claim 11, wherein the one or more sensor boards are configured to condition sensor outputs from one or more of a temperature sensor, a force sensor, a humidity sensor, a pressure sensor, a displacement sensor, an acceleration sensor, or a velocity sensor.

13. The monitoring system of claim 11, wherein the communications board includes one or more couplers for wired communications with one or more external computing devices and/or one or more wireless communication modules to facilitate wireless communications with the one or more external computing devices.

14. The monitoring system of claim 11, wherein each of the plurality of stacked circuit boards and the displacement sensor board have a cross-sectional shape comprising one of: disk-shaped, doughnut-shaped, or arc-shaped.

15. A shock absorber monitoring system comprising:
a plurality of stacked circuit boards comprising:
one or more sensor boards, each sensor board configured to condition a sensor output from a sensor;
a processor board coupled to the one or more sensor boards and configured to process signals associated with sensor outputs from the one or more sensor boards;
a communications board coupled to the processor board, the communications board comprising one or more communication modules configured to facilitate exchange of data and instructions with the processor board; and
a power supply board electrically coupled to: the one or more sensor boards, the processor board, and the communications board, wherein the power supply board is configured to provide power to components of the monitoring system and includes a battery, power supply circuitry, and a charger module to charge the battery;
wherein a stacking order of the plurality of stacked circuit boards is configurable, and the plurality of stacked circuit boards is arranged to fit inside a portion of a shock absorber.

16. The monitoring system of claim 15, wherein the charger module comprises a piezoelectric power generator or a thermoelectric power generator to generate charging power from the shock absorber.

17. The monitoring system of claim 15, wherein the charger module comprises a coupler for an external solar power generator to supply charging power.

18. A method for manufacturing a shock absorber monitoring system, the method comprising:
forming a plurality of stacked circuit boards by:
assembling one or more sensor boards, each sensor board including circuitry configured to condition a sensor output from a sensor;
assembling a processor board including one or more processors configured to process signals associated with sensor outputs from the one or more sensor boards;
assembling a communications board including one or more communication modules configured to facilitate exchange of data and instructions with the processor board;
assembling a power supply board configured to provide power to components of the monitoring system; and
coupling the one or more sensor boards, the processor board, the communications board, and the power supply board together through stacking, wherein a stacking order of the plurality of stacked circuit boards is configurable; and
fitting the coupled plurality of stacked circuit boards inside a portion of a shock absorber.

19. The method of claim 18, wherein assembling the one or more sensor boards comprises:
configuring at least one of the one or more sensor boards to condition sensor outputs from two or more distinct sensors and configuring at least one other of the one or more sensor boards to condition the sensor output from a single sensor; and
configuring each of the one or more sensor boards to condition sensor outputs from one or more of a temperature sensor, a force sensor, a pressure sensor, a displacement sensor, an acceleration sensor, or a velocity sensor.

20. The method of claim 18, further comprising:
assembling a displacement sensor board including a laser displacement module;
disposing the displacement sensor board outside a body of the shock absorber such that the displacement module measures a displacement of a shock cap of the shock absorber relative to the body of the shock absorber; and
disposing one or more of a piezoelectric power generator or a thermoelectric power generator on the power supply board to generate charging power from the shock absorber, or a connection for an external solar power generator on the power supply board to generate charging power.
